(19) United States
(12) Patent Application Publication
(10) Pub. No.: US 2008/0305594 A1
(43) Pub. Date: Dec. 11, 2008

(54) METHOD FOR FABRICATING NON-VOLATILE MEMORY

(75) Inventors: Chung-We Pan, Pingtung County (TW); Shou-Yu Chang, Hsinchu City (TW); Tzeng-Wen Tzeng, Taoyuan County (TW); Ching-Hung Fu, Hsinchu City (TW); Chih-Ping Chung, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: PROMOS TECHNOLOGIES INC., Hsinchu (TW)

(21) Appl. No.: 11/828,344

(22) Filed: Jul. 25, 2007

(30) Foreign Application Priority Data
Jun. 7, 2007 (TW) 96120515

(51) Int. Cl. H01L 21/336

(52) U.S. Cl. 438/264; 257/E21.422

(57) ABSTRACT

A method for fabricating a non-volatile memory is provided. Parallel-arranged isolation structures are disposed in a substrate and protrude from the surface of the substrate to define active regions. Mask layers intersecting the isolation structures are deposited on the substrate. The surface of the mask layers is higher than that of the isolation structures. Doped regions are formed in the substrate. Insulating layers are deposited on the substrate between the mask layers. The insulating layers and the mask layers have different etch selectivities. The mask layers are removed to expose the substrate. A tunneling dielectric layer is formed on the substrate. A floating gate is deposited on the substrate surrounded by the isolation structures and the insulating layers. The surface of the floating gate is lower than that of the isolation structures. An inter-gate dielectric layer is deposited on the substrate. A control gate is disposed between the insulating layers.

### CROSS-REFERENCE TO RELATED APPLICATION

This application claims the priority benefit of Taiwan application serial no. 96120515, filed Jun. 7, 2007. All disclosure of the Taiwan application is incorporated herein by reference.

### BACKGROUND OF THE INVENTION

1. Field of the Invention

The present invention relates to a method for fabricating a semiconductor device, more particularly, to a method for fabricating a non-volatile memory.

2. Description of Related Art

Memory is a semiconductor device designed to store information or data. As microprocessors develop and the complexity of programming and operation performed by software is further increased, the demand for memory with larger storage capacity increases. Therefore, memory fabrication is one of the important techniques in the semiconductor industry. Generally, memory can be categorized into volatile memory and non-volatile memory depending on the storage type of the memory. For example, flash memory is a type of non-volatile memory. Flash memory allows multiple data writing, reading and erasing. The stored data is retained even when not powered. With these advantages, flash memory has become one of the most widely adopted non-volatile memory for personal computers and electronic equipments.

As the demand for non-volatile memory with higher level of integration increases, the dimensions of memory cells are shrinkage to improve the level of integration in memory. A typical non-volatile memory is generally a gate structure composed of a floating gate and a control gate. The floating gate is disposed between the control gate and the substrate in a floating state that is not connected to any circuit. The control gate is connected to a word line. Further, a tunneling dielectric layer is disposed between the substrate and the floating gate, and an inter-gate dielectric layer is disposed between the floating gate and the control gate.

Nevertheless, multiple photolithography processes and etching processes are usually required to define the floating gate and the control gate when fabricating a non-volatile memory with the aforementioned gate structure. Additionally, the level of alignment accuracy required for fabricating a floating gate and a control gate is high. Hence, it is not easy to control the fabrication process. More specifically, if misalignment happens when forming the floating gate or the control gate, the fabrication steps ensued are affected, and the reliability of the non-volatile memory thus formed is lowered. Moreover, a photomask used in a photolithography process is usually the more expensive part in a semiconductor fabrication process. In other words, when more photomasks are used, the manufacturing costs and the time needed for the fabrication process to complete increase.

As a result, how to fabricate a non-volatile memory using a simplified and easy-to-control method while maintaining the reliability of the memory fabricated is an immediate problem to be resolved by the industry.

### SUMMARY OF THE INVENTION

Accordingly, the present invention is directed to a method for fabricating a non-volatile memory that forms a self-aligned gate structure and prevents the gate structure from misaligning.

The present invention is also directed to a method for fabricating a non-volatile memory that utilizes simplified fabrication steps and decreases the number of photomasks used to lower the manufacturing costs.

The present invention is directed to a method for fabricating a non-volatile memory that includes the following steps. First, a substrate is provided and isolation structures are formed to define active regions. The isolation structures are arranged in parallel and protrude from the surface of the substrate. Next, mask layers are formed on the substrate. The mask layers intersect the isolation structures. The surface of the mask layers is higher than that of the isolation structures. Thereafter, doped regions are formed in the substrate. Afterward, insulating layers are deposited on the substrate between the adjacent mask layers. The insulating layers and the mask layers are fabricated using materials with different etch selectivities. Subsequently, the mask layers are removed to expose the substrate. Then, a tunneling dielectric layer is formed on the substrate. Floating gates are deposited on the substrate surrounded by the isolation structures and the insulating layers. The surface of the floating gates is lower than that of the isolation structures. Ensuingly, an inter-gate dielectric layer is formed on the substrate. Further, control gates are formed between the insulating layers and intersect the active regions.

According to one embodiment of the present invention, the control gates and select gates are formed simultaneously after the inter-gate dielectric layer is formed on a substrate.

According to one embodiment of the present invention, the aforementioned floating gates are fabricated, for example, by forming a first conductor layer on a substrate. Next, a portion of the first conductor layer is removed.

According to one embodiment of the present invention, a portion of the aforementioned first conductor layer is removed, for example, by a dry etching process.

According to one embodiment of the present invention, the material used for fabricating the aforementioned first conductor layer is, for example, doped polysilicon.

According to one embodiment of the present invention, the aforementioned inter-gate dielectric layer is, for example, a silicon oxide/silicon nitride/silicon oxide (ONO) layer.

According to one embodiment of the present invention, the steps for forming the control gates between the adjacent insulating layers include, for example, forming a second conductor layer on the substrate, followed by removing a portion of the second conductor layer to expose the surface of the insulating layers.

According to one embodiment of the present invention, the method used for removing a portion of the second conductor layer is, for example, a chemical mechanical polishing process.

According to one embodiment of the present invention, the material used for fabricating the aforementioned second conductor layer is, for example, doped polysilicon.

According to one embodiment of the present invention, the material used for fabricating the aforementioned tunneling dielectric layer is, for example, silicon oxide.

The present invention is also directed to another method for fabricating a non-volatile memory. First, a substrate is provided and isolation structures are formed to define active regions. The isolation structures are arranged in parallel and protrude from the surface of the substrate. Next, mask layers are formed on the substrate. The mask layers intersect the isolation structures. The surface of the mask layers is higher than that of the isolation structures. Thereafter, doped regions are formed in the substrate. Afterward, insulating layers are formed on the substrate between the adjacent mask layers. The insulating layers and the mask layers are fabricated using materials with different etch selectivities. Subsequently, the mask layers are removed to expose the substrate. After a tunneling dielectric layer is formed on the substrate, a charge trapping layer is compliantly formed on the substrate. Further, control gates are formed between the insulating layers and intersect the active regions.

According to one embodiment of the present invention, after the formation of the charge trapping layer, a portion of the charge trapping layer is removed for forming select gates, followed by the select gates and the control gates are formed simultaneously.

According to one embodiment of the present invention, a top dielectric layer is formed between the control gates and the charge trapping layer.

According to one embodiment of the present invention, the material used for fabricating the top dielectric layer is, for example, silicon oxide or aluminum oxide.

According to one embodiment of the present invention, the material used for fabricating the charge trapping layer is, for example, silicon nitride.

According to one embodiment of the present invention, the steps for forming the control gates between the adjacent insulating layers include, for example, forming a conductor layer on the substrate, followed by removing a portion of the conductor layer to expose the surface of the insulating layers.

According to one embodiment of the present invention, the method used for removing a portion of the conductor layer is, for example, a chemical mechanical polishing process.

According to one embodiment of the present invention, the material used for fabricating the aforementioned conductor layer is, for example, doped polysilicon.

According to one embodiment of the present invention, the material used for fabricating the tunneling dielectric layer is, for example, silicon oxide.

According to the present invention, the method for fabricating a non-volatile memory utilizes a damascene process to fabricate the charge storage structure and the word line. Hence, a photolithography process and an etching process are not performed directly to the conductor material layer, avoiding misalignment.

Further, the steps of performing a photolithography process and an etching process are omitted when fabricating the gate structure according to the present invention. Also, the formation of spacers for protecting conductor material is not required. As a result, the present invention can greatly lower the manufacturing costs and increase the level of integration in a device using simplified fabrication steps to increase the process window.

In order to make the aforementioned and other features and advantages of the present invention more comprehensible, preferred embodiments accompanied with figures are described in detail below.

### BRIEF DESCRIPTION OF THE DRAWINGS

FIGS. 1A through 6A are schematic top views illustrating a method for fabricating a non-volatile memory according to one embodiment of the present invention.

FIGS. 1B through 6B are schematic cross-sectional views of FIGS. 1A through 6A along the line I-I′.

FIGS. 1C through 6C are schematic cross-sectional views of FIGS. 1A through 6A along the line II-II′.

FIGS. 1D through 6D are schematic cross-sectional views of FIGS. 1A through 6A along the line III-III′.

FIGS. 7A and 8A are schematic top views illustrating a method for fabricating a non-volatile memory according to another embodiment of the present invention.

FIGS. 7B and 8B are schematic cross-sectional views of FIGS. 7A and 8A along the line I-I′.

FIGS. 7C and 8C are schematic cross-sectional views of FIGS. 7A and 8A along the line II-II′.

FIGS. 7D and 8D are schematic cross-sectional views of FIGS. 7A and 8A along the line III-III′.

### DESCRIPTION OF EMBODIMENTS

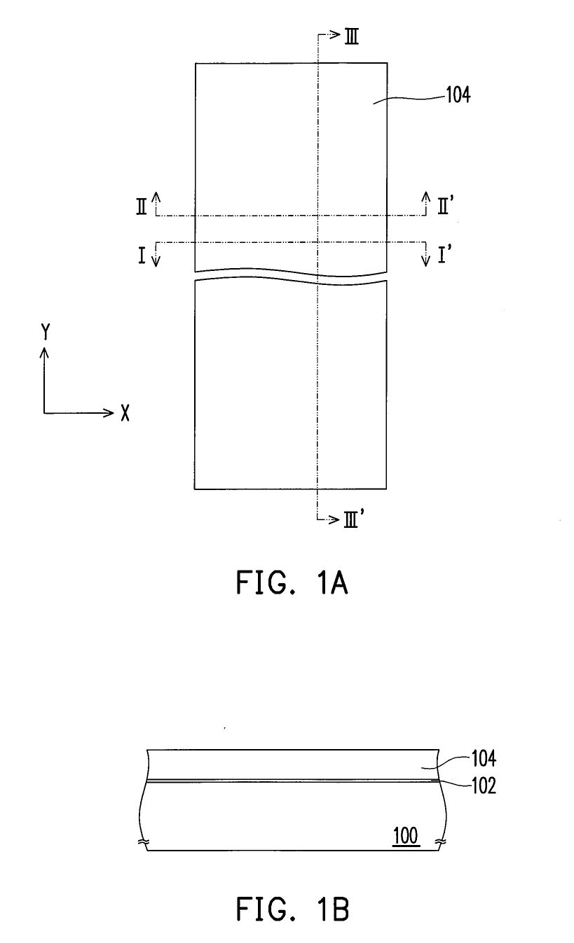

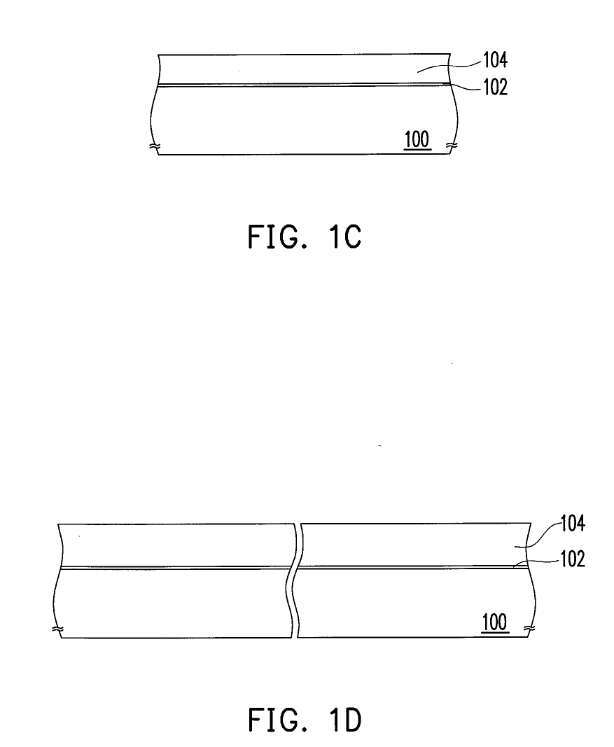

FIGS. 1A through 6A are schematic top views illustrating a method for fabricating a non-volatile memory according to one embodiment of the present invention. FIGS. 1B through 6B are schematic cross-sectional views of FIGS. 1A through 6A along the line I-I′. FIGS. 1C through 6C are schematic cross-sectional views of FIGS. 1A through 6A along the line II-II′. FIGS. 1D through 6D are schematic cross-sectional views of FIGS. 1A through 6A along the line III-III′.

Referring to FIGS. 1A, 1B, 1C, and 1D, a substrate 100 is provided. The substrate 100 is, for example, a silicon substrate. Then, a hard mask layer 104 is formed on the substrate 100. The material used for fabricating the hard mask layer 104 is, for example, silicon nitride, and the method used for fabricating the same is, for example, a chemical vapor deposition process. Further, prior to forming the hard mask layer 104, a pad oxide layer 102 may be optionally formed on the surface of the substrate 100. The pad oxide layer 102 is used to increase the adhesion between the hard mask layer 104 and the substrate 100, for example. The material used for fabricating the pad oxide layer 102 is, for example, silicon oxide, and the method for fabricating the same is, for example, a thermal oxidation process.

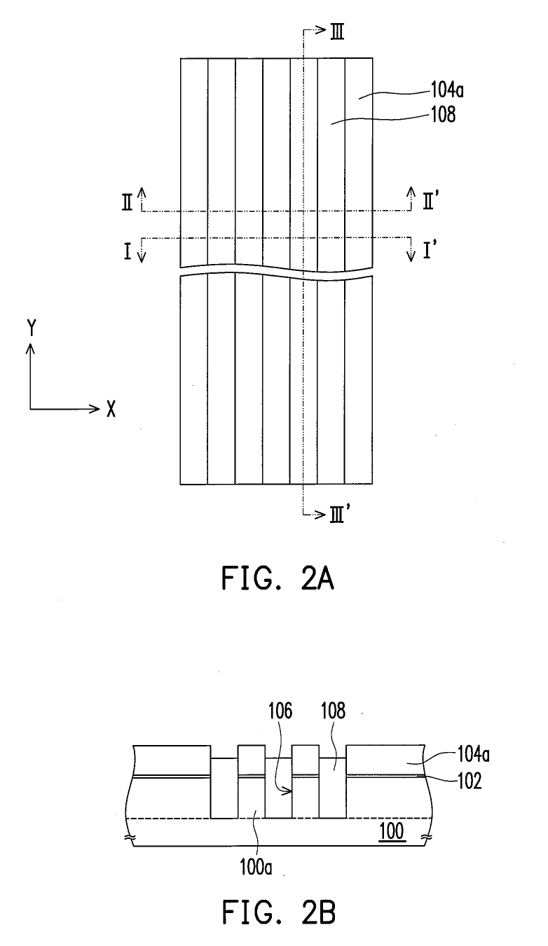

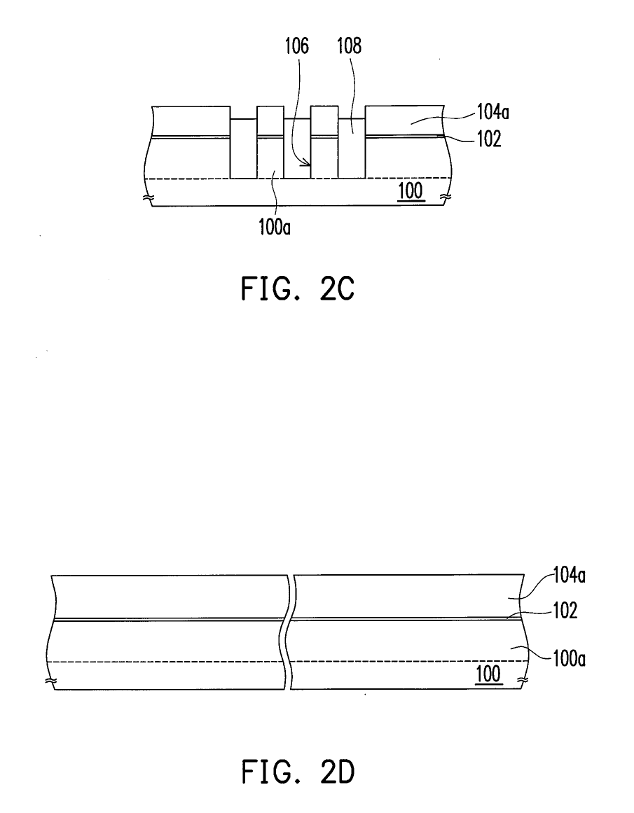

Referring to FIGS. 2A, 2B, 2C, and 2D, the hard mask layer 104 and the pad oxide layer 102 are patterned to form a patterned hard mask layer 104a and openings (not shown) that expose the surface of the substrate 100. Next, the patterned hard mask layer 104a is used as a mask to remove a portion of the substrate 100, so as to form trenches 106 in the substrate 100. The method used for removing a portion of the substrate 100 is, for example, a dry etching process. Thereafter, isolation structures 108 are formed in the trenches 106. The method used for forming the isolation structures 108 includes first forming an insulating material layer (not shown) filling the trenches 106, followed by removing a portion of the insulating material layer to planarize the surface of the insulating material layer to form isolation structures 108, for example. The material used for fabricating the insulating material layer is, for example, silicon oxide, and the method used for fabricating the same is, for example, a high density plasma chemical vapor deposition process. The method used for removing a portion of the insulating material layer is, for example, a chemical mechanical polishing process or a dry etching back process.

In view of the above, the surface of the isolation structures 108 is lower than that of the patterned hard mask layer 104a, and higher than that of the substrate 100, for example. In other words, there is a step height between the patterned hard mask layer 104a and the isolation structures 108, for example. The isolation structures 108 are arranged in parallel, and extend in the Y-direction (as shown in FIG. 2A) to define active regions 100a. The active regions 100a are, for example, disposed between two adjacent isolation structures 108. The active regions 100a are, for example, arranged in parallel and extend in the Y-direction.

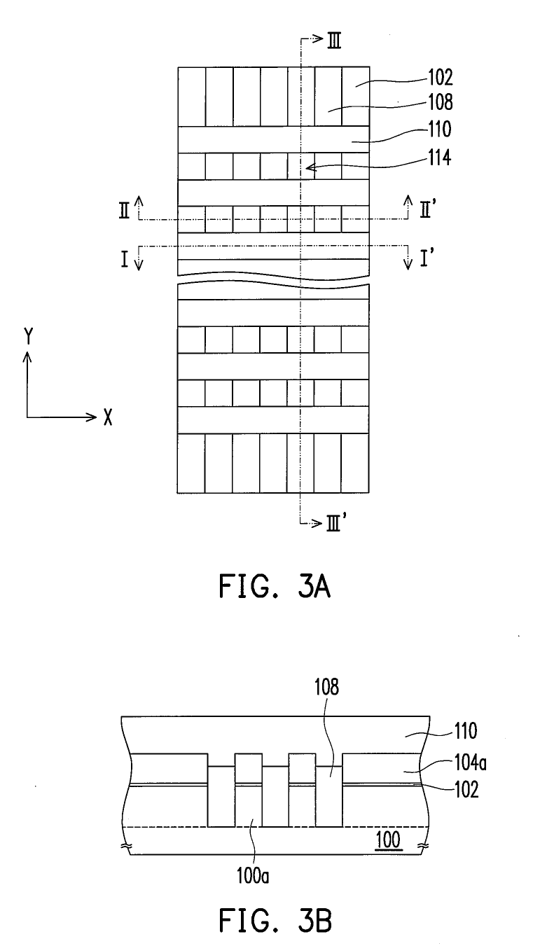

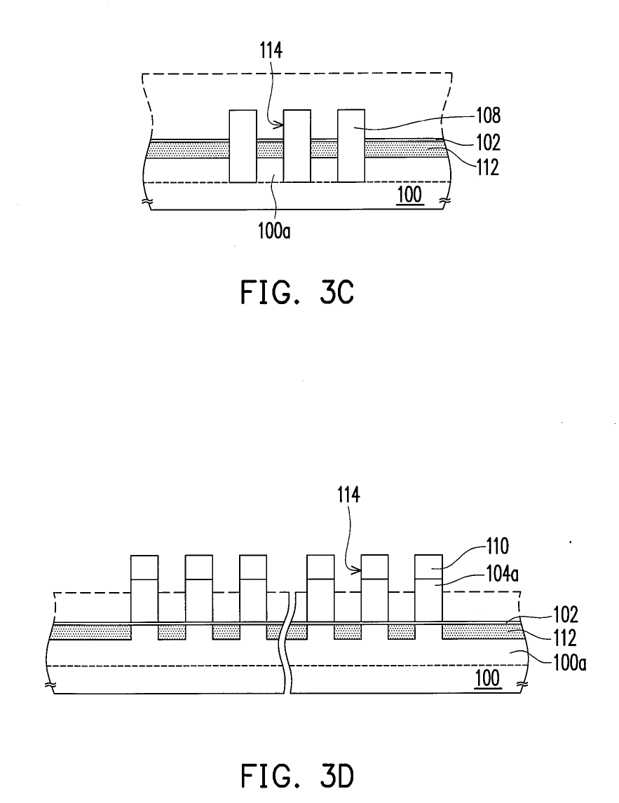

Referring to FIGS. 3A, 3B, 3C, and 3D, a mask material layer (not shown) is formed on the substrate 100. The mask material layer, for example, covers the isolation structures 108 and the patterned hard mask layer 104a. The material used for fabricating the mask material layer is, for example, silicon nitride, and the method used for fabricating the same is, for example, a chemical vapor deposition process. Thereafter, the mask material layer is patterned to form a mask layer 110. Since the patterned hard mask layer 104a and the mask material layer are fabricated using the same material, a portion of the patterned hard mask layer 104a is removed to expose a portion of the isolation structures 108 and the pad oxide layer 102 when the mask material layer is patterned. As a result, the mask layer 110 is, for example, a striped structure, forming a palisade formation on the substrate 100. The mask layer 110, for example, extends in the X-direction, and intersects the isolation structures 108 (as shown in FIG. 3A). The mask layer 110 and the isolation structures 108, for example, form openings 114 on the substrate 100. In addition, the surface of the mask layer 110 is, for example, higher than that of the isolation structures 108.

Afterward, doped regions 112 are formed in the substrate 100 at the openings 114. The doped regions 112 may be formed by an ion implantation process. The doped regions 112 disposed in the active regions 100a are, for example, used as a source/drain region of the non-volatile memory.

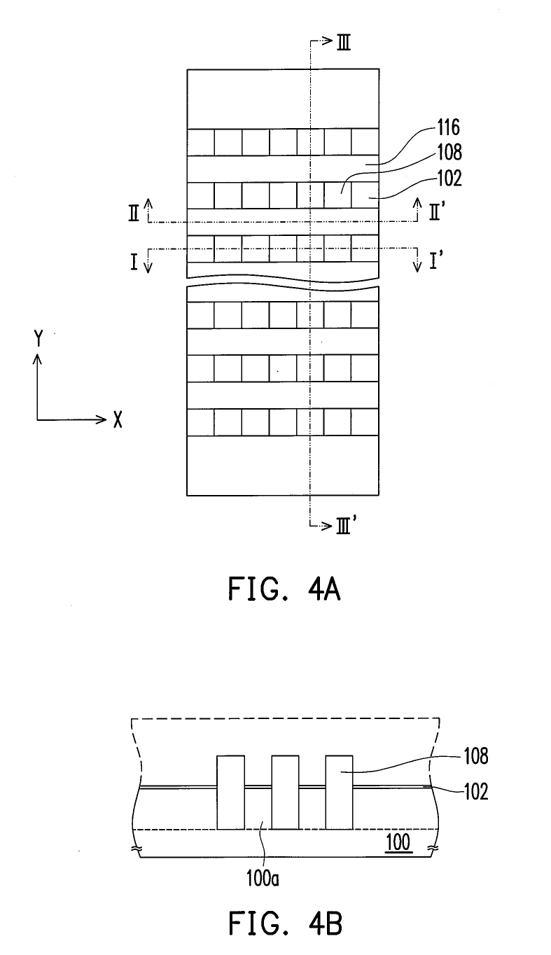

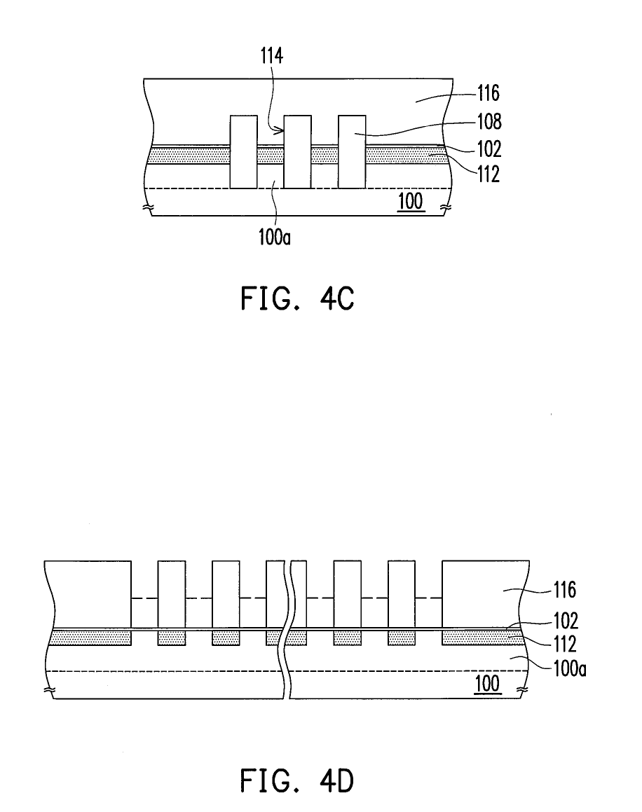

Referring to FIGS. 4A, 4B, 4C and 4D, an insulating layer 116 is formed on the substrate 100. The insulating layer 116 is, for example, filled into the openings 114. The material used for fabricating the insulating layer 116 is, for example, silicon oxide, and the method used for fabricating the same is, for example, a high density plasma chemical vapor deposition process. Next, a planarization process is performed to planarize the surface of the insulating layer 116. The method used for planarizing the insulating layer 116 is, for example, a chemical mechanical polishing process. When the surface of the insulating layer 116 is planarized, the mask layer 110 is used as a polish stop layer. Hence, the insulating layer 116 forms a structure with a plurality of bars, for example. The insulating layer 116 is disposed between two adjacent mask layers 110, and extends in the X-direction (as shown in FIG. 4A), for example.

Next, the patterned hard mask layer 104a and the mask layer 110 are removed. The method used for removing the patterned hard mask layer 104a and the mask layer 110 is, for example, a wet etching process or a dry etching process. The material used for fabricating the patterned hard mask layer 104a and the mask layer 110 is, for example, silicon nitride. The patterned hard mask layer 104a and the mask layer 110 may be simultaneously removed. Therefore, the insulating layer 116 intersects the isolation structures 108, for example.

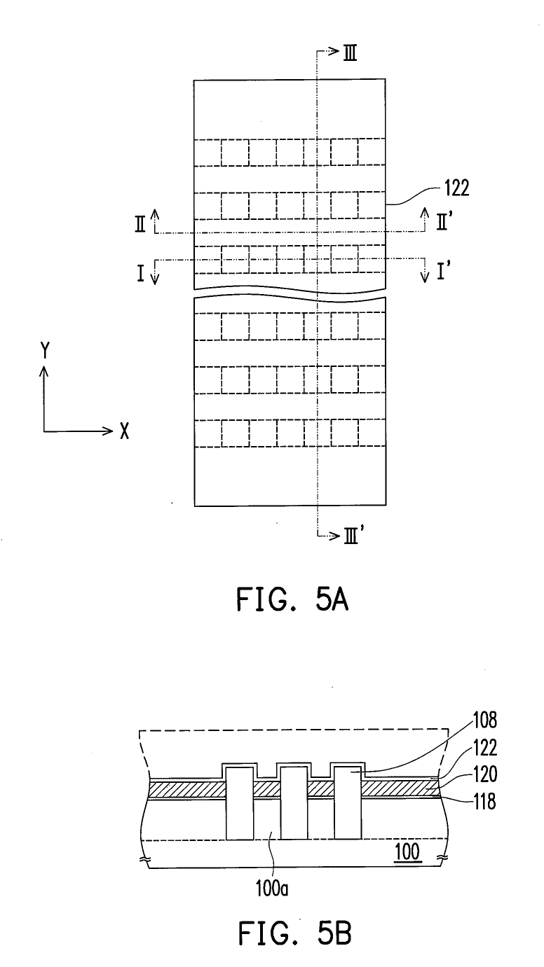

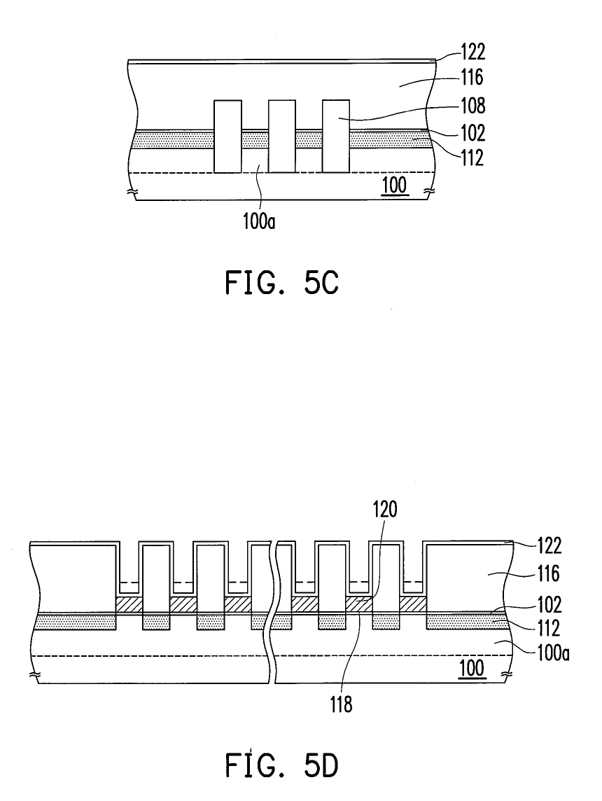

Referring to FIGS. 5A, 5B, 5C and 5D, the insulating layer 116 is removed to expose the pad oxide layer 102. The pad oxide layer 102 removed is disposed on the substrate 100 surrounded by the isolation structures 108 and the insulating layer 116, for example. The method used for removing the pad oxide layer 102 is, for example, a wet etching process or a dry etching process. Next, a dielectric layer 118 is formed on the substrate 100 where the pad oxide layer 102 is removed. The material used for fabricating the dielectric layer 118 is, for example, silicon oxide, and the method used for fabricating the same is, for example, a thermal oxidation process or a chemical vapor deposition process. The dielectric layer 118 is used as a tunneling dielectric layer of the non-volatile memory, for example.

Further, a cleaning process may be optionally performed to completely remove the materials remained on the substrate 100 after the removal of the pad oxide layer 102 and before the formation of the dielectric layer 118. Therefore, the occurrence of current leakage in the memory caused by defects in the dielectric layer 118 can be avoided.

In view of the above, the threshold voltage may be adjusted by implanting ions to a specific channel region in the non-volatile memory after the removal of the patterned hard mask layer 104a and the mask layer 110 and before the removal of the exposed pad oxide layer 102. Those of ordinary skill in the art can make necessary adjustment based on the actual requirements.

Thereafter, a charge storage layer 120 is formed on the substrate 100. Herein, the active regions 100a between the adjacent isolation structures 108 are filled with the charge storage layer 120, for example. The material used for fabricating the charge storage layer 120 is, for example, doped polysilicon or other suitable conductor material. The method used for fabricating the charge storage layer 120 includes, for example, first performing a chemical vapor deposition process to form undoped polysilicon layer, followed by performing an ion implantation process to dope the polysilicon layer; or performing a chemical vapor deposition process with an in-situ dopant implantation to form a doped polysilicon layer.

Next, a portion of the charge storage layer 120 is removed to expose the isolation structures 108, so as to make the surface of the charge storage layer 120 lower than that of the isolation structures 108. The method used for removing a portion of the charge storage layer 120 is, for example, a dry etching process. After a portion of the charge storage layer 120 is removed, the charge storage layer 120 is disposed on the substrate 100 surrounded by the isolation structures 108 and the insulating layer 116, for example. Further, the remaining portion of the charge storage layer 120 is used as a floating gate of the non-volatile memory, for example. In other words, a plurality of floating gates is formed on the active regions 100a between adjacent isolation structures 108, for example. Further, the floating gates are, for example, disposed between two doped regions 112.

Next, a dielectric layer 122 is formed on the substrate 100. The dielectric layer 122 compliantly covers the isolation structures 108, the charge storage layer 120, and the insulating layer 116, for example. The material used for fabricating the dielectric layer 122 is, for example, silicon oxide, silicon nitride or a combination thereof. In the present embodiment, the dielectric layer 122 is a silicon oxide/silicon nitride/silicon oxide (ONO) layer. The method used for fabricating the dielectric layer 122 includes, for example, first performing a chemical vapor deposition process or a thermal oxidation process to form a silicon oxide layer, followed by performing a chemical vapor deposition process to form a silicon nitride layer on the first silicon oxide layer, and performing a chemical vapor deposition process to form the second silicon oxide layer on the silicon nitride layer.

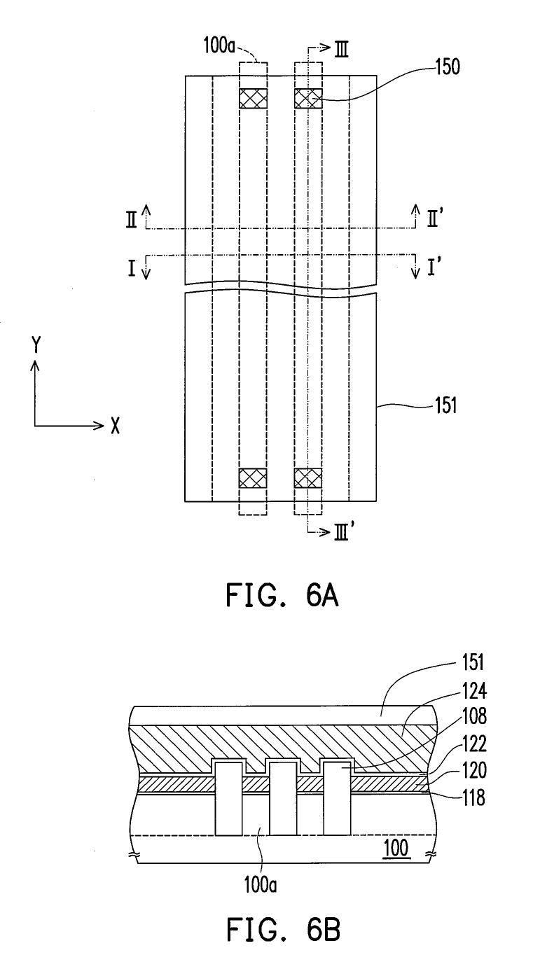

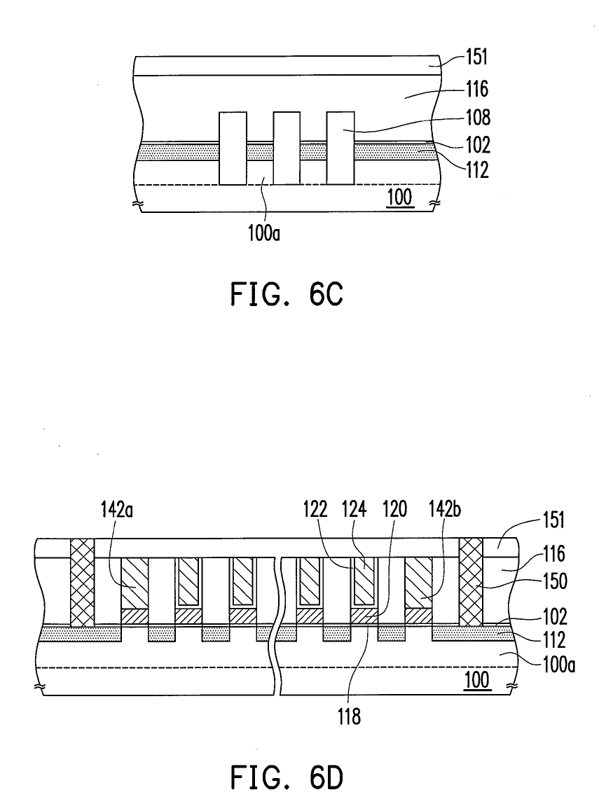

Referring to FIGS. 6A, 6B, 6C and 6D, another patterned mask layer (not shown) is formed on the substrate 100. Further, regions for forming select gates are exposed by the patterned mask layer. The material used for fabricating the patterned mask layer is, for example, a photoresist material, and the method used for fabricating the same includes, for example, first forming a photoresist layer on the substrate 100, followed by performing an exposure process and a development process. Thereafter, the dielectric layer 122 exposed by the patterned mask layer is removed to expose the charge storage layer 120. The method used for removing a portion of the dielectric layer 122 is, for example, a dry etching process or a wet etching process. Afterward, the patterned mask layer is removed.

Subsequently, a conductor layer 124 is formed on the substrate 100. The conductor layer 124 compliantly covers the charge storage layer 120 and the isolation structures 108, for example. The material used for fabricating the conductor layer 124 is, for example, doped polysilicon or other suitable conductor material. The method used for fabricating the conductor layer 124 includes, for example, first performing a chemical vapor deposition process to form an undoped polysilicon layer, followed by performing an ion implantation process to dope the polysilicon layer; or performing a chemical vapor deposition process with an in-situ doping operation to form a doped polysilicon layer.

Then, a portion of the conductor layer 124 is removed to expose the insulating layer 116. The method used for removing a portion of the insulating material layer 124 is, for example, a chemical mechanical polishing process or a dry etching back process. During the process of removing a portion of the conductor layer 124, the insulating layer 116 is used as a polish stop layer or an etch stop layer, for example. After the portion of the conductor layer 124 is removed, a structure with a plurality of parallel bars is formed, for example. The remaining portion of the conductor layer 124 fills the space between the adjacent isolation structures 108, for example. Further, the remaining portion of the conductor layer 124 crosses the active regions 100a to form a plurality of word lines and select gate lines 142a and 142b. The word lines and the select gate lines 142a and 142b extend in the X-direction (as shown in FIG. 6A), for example. Each word line is disposed between two insulating layers 116, for example. The word lines are arranged in a bar layout, for example. As a result, the word lines, for example, intersect the active regions 100a. The intersections between the word lines and the active regions 100a form the memory cells of the non-volatile memory. On the other hand, the portion of the active regions 100a crossed by the word lines form, for example, control gates of the memory cells.

In view of the above, the select gate lines 142a and 142b are, for example, respectively disposed on the both outermost sides of the word lines. The intersections between the select gate lines 142a and 142b and the active regions 100a respectively form select units of the non-volatile memory. Herein, the portion of the active regions 100a crossed by the select gate lines 142a and 142b form, for example, select gates of the select units.

Next, an insulating layer 151 is formed. The material used for fabricating the insulating layer 151 is, for example, silicon oxide, and the method for fabricating the same is, for example, a chemical vapor deposition method. Portions of the insulating layers 151, 116 and the pad oxide layer 102 are removed to form openings (not shown). A portion of the doped regions 112 is exposed by the openings, for example. The method used for forming the openings includes, for example, a photolithography process and an etching process. Thereafter, a conductor layer 150 is formed in the openings. The conductor layer 150 is used as a bit line contact plug for connecting bit lines in the non-volatile memory, for example. The method used for forming the conductor layer 150 in the openings include forming a conductor material layer that fills the openings on the substrate 100, followed by performing a chemical mechanical polishing process or a dry etching back process to remove a portion of the conductor material layer till the insulating layer 151 is exposed, for example.

Afterward, a plurality of bit lines (not shown) is further formed on the substrate 100. The bit lines are electrically connected to the doped regions 112 through the conductor layer 150, for example. The method for fabricating bit lines and the subsequent fabrication process required to complete the non-volatile memory should be apparent to one of ordinary skill in the art. Hence, a detailed description thereof is omitted.

It should be noted that, as shown in FIG. 6D, the dielectric layer 118 in the active regions 100a is used as the tunneling dielectric layer in the non-volatile memory, for example. The charge storage layer 120 is used as the floating gate of the non-volatile memory, for example. The doped regions 112 disposed on the both sides of the charge storage layer 120 are, for example, used as the source/drain regions of the non-volatile memory. The conductor layer 124 is, for example, used as the control gate and the word lines of the non-volatile memory. The dielectric layer 122 disposed between the charge storage layer 120 and the conductor layer 124 is used as the inter-gate dielectric layer of the non-volatile memory, for example.

It should be noted that, in the above-mentioned embodiment, a damascene process is used to form a self-aligned structure when fabricating the floating gate and the control gate. No photolithography process and etching process are required to be performed during the formation of the gate structure. Therefore, the method for fabricating a non-volatile memory of the present invention can avoid the occurrence of misalignment and increase the process window.

Besides the aforementioned embodiment, the present invention is also directed to another method for fabricating a non-volatile memory.

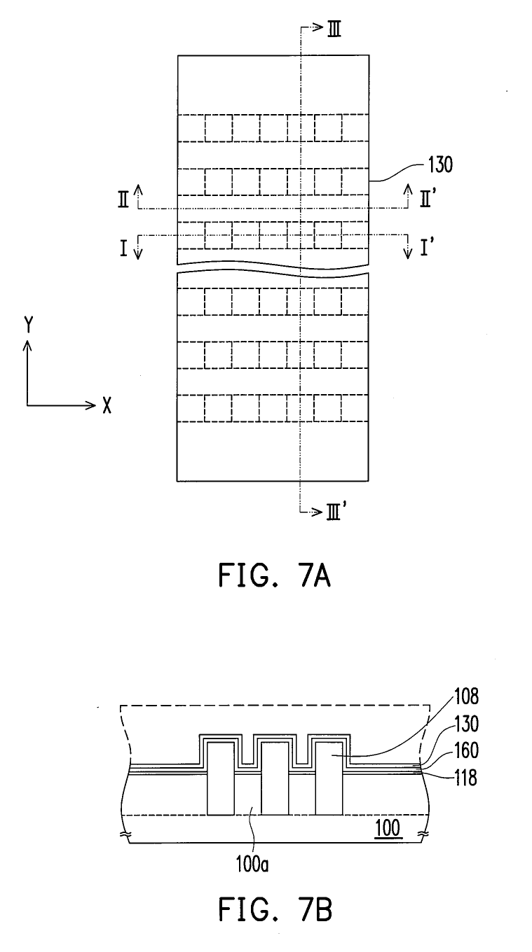

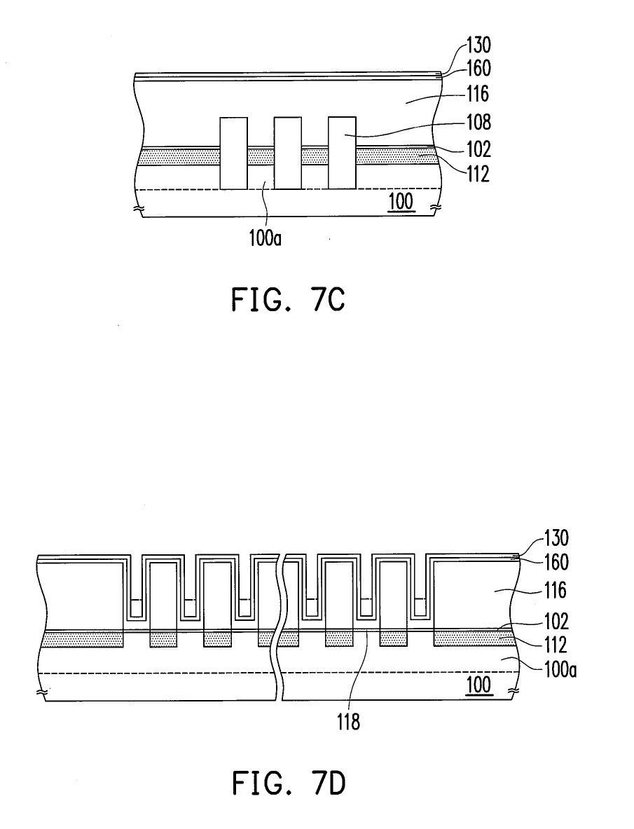

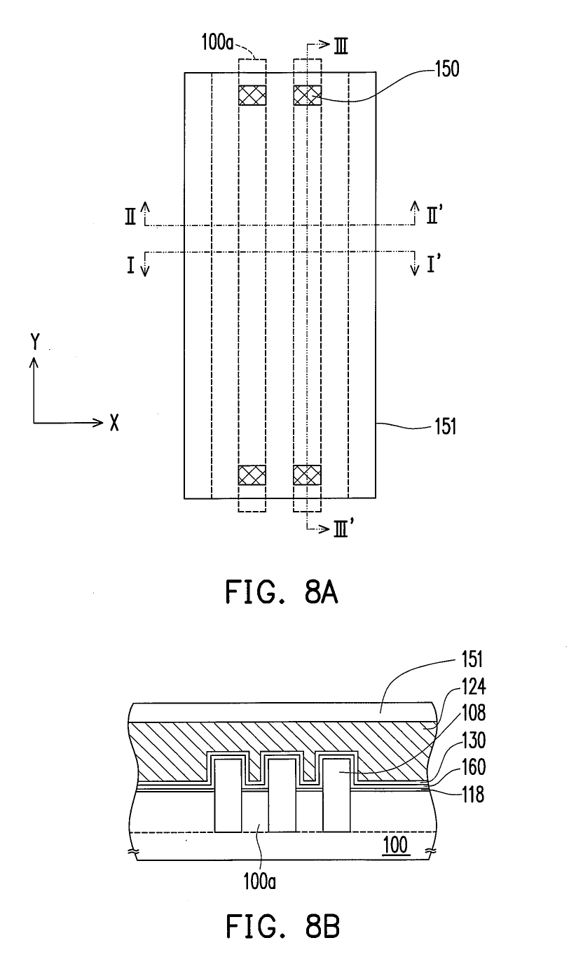

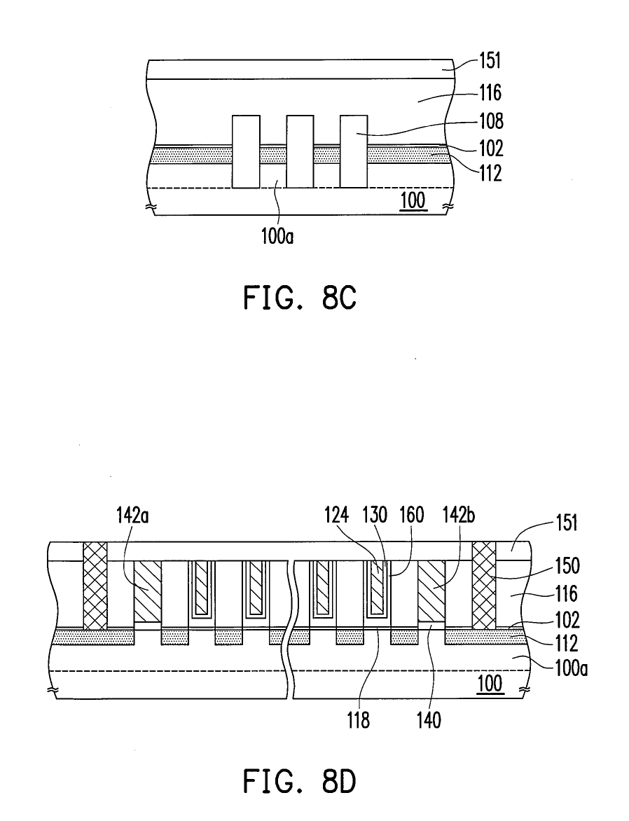

FIGS. 7A and 8A are schematic top views illustrating a method for fabricating a non-volatile memory according to another embodiment of the present invention. FIGS. 7B and 8B are schematic cross-sectional views of FIGS. 7A and 8A along the line I-I′. FIGS. 7C and 8C are schematic cross-sectional views of FIGS. 7A and 8A along the line II-II′. FIGS. 7D and 8D are schematic cross-sectional views of FIGS. 7A and 8A along the line III-III′. FIGS. 7A through 7D illustrate steps that are subsequent to the aforementioned embodiment shown in FIGS. 4A through 4D. The same reference numerals used in FIGS. 1A through 6D are used to refer to the same elements in FIGS. 7A and 8D. Hence, a detailed description thereof is omitted.

Referring to FIGS. 7A, 7B, 7C and 7D, the insulating layer 116 is removed to expose the pad oxide layer 102. The pad oxide layer 102 removed is disposed on the substrate 100 surrounded by the isolation structures 108 and the insulating layer 116, for example. The method used for removing the pad oxide layer 102 is, for example, a wet etching process or a dry etching process. Then, a dielectric layer 118 is formed on the substrate 100 where the pad oxide layer 102 is removed, for example. The material used for fabricating the dielectric layer 118 is, for example, silicon oxide, and the method used for fabricating the same is, for example, a thermal oxidation process or a chemical vapor deposition process.

Thereafter, a charge trapping layer 160 compliantly forms on the substrate 100. The material used for fabricating the charge trapping layer 160 is, for example, a material that traps charges such as silicon nitride, tantalum silicon oxide, strontium silicon titanate or hafnium silicon oxide. Further, the method used for fabricating the charge trapping layer 160 is, for example, a chemical vapor deposition process.

Afterward, a dielectric layer 130 is formed on the substrate 100. The dielectric layer 130, for example, compliantly covers the charge trapping layer 160. The material used for fabricating the dielectric layer 130 is, for example, silicon oxide, aluminum oxide or other suitable dielectric material. The method used for fabricating the dielectric layer 130 is, for example, a chemical vapor deposition process.

Referring to FIGS. 8A, 8B, 8C and 8D, a patterned mask layer (not shown) is formed on the substrate 100. Further, regions for forming select gates are exposed by the patterned mask layer. The material used for fabricating the patterned mask layer is, for example, a photoresist material, and the method used for fabricating the same includes, for example, first forming a photoresist layer on the substrate 100, followed by performing an exposure process and a development process. Thereafter, the dielectric layer 130, the charge trapping layer 160, and the dielectric layer 118 exposed by the patterned mask layer are removed. In other words, portions of the dielectric layer 130, the charge trapping layer 160, and the dielectric layer 118 are removed for forming the select gates. The method used for removing portions of the dielectric layer 130, the charge trapping layer 160, and the dielectric layer 118 is, for example, a dry etching process or a wet etching process. Next, the patterned mask layer is removed. A dielectric layer 140 is formed on the regions for forming the select gates. The material used for fabricating the dielectric layer 140 is, for example, silicon oxide, and the method used for fabricating the same is, for example, a thermal oxidation process or a chemical vapor deposition process. This dielectric layer 140 may be used as a select gate dielectric layer.

Certainly, in another embodiment, the dielectric layer 130 and the charge trapping layer 160 in the positions of the select gates may not be removed, and the dielectric layer 140 may not be formed. Instead, the dielectric layer 130 and the charge trapping layer 160 are used directly as the select gate dielectric layer of the select units.

Thereafter, a conductor layer 124 is formed on the substrate 100. The conductor layer 124, for example, covers the dielectric layer 130. The material used for fabricating the conductor layer 124 is doped polysilicon or other suitable conductor material, for example. The method used for fabricating the conductor layer 124 includes first performing a chemical vapor deposition process to form an undoped polysilicon layer, followed by performing an ion implantation process to dope the polysilicon layer; or performing a chemical vapor deposition process with an in-situ dopant implantation to form a doped polysilicon layer, for example.

Then, a portion of the conductor layer 124 is removed to expose the insulating layer 116. The method used for removing a portion of the conductor layer 124 is, for example, a chemical mechanical polishing process or a dry etching back process. When a portion of the conductor layer 124 is removed, the insulating layer 116 is used as a polish stop layer or an etch stop layer, for example. After the portion of the conductor layer 124 is removed, a structure with a plurality of parallel bars is formed, for example. The remaining portion of the conductor layer 124 fills the space between the adjacent isolation structures 108, for example. Further, the remaining portion of the conductor layer 124 crosses the active regions 100a to form a plurality of word lines, and select gate lines 142a and 142b. The word lines and the select gate lines 142a and 142b extend in the X-direction (as shown in FIG. 8A), for example. Each word line is disposed between two insulating layers 116, for example. The word lines are arranged in a bar layout, for example. As a result, the word lines intersect the active regions 100a, for example. The intersections between the word lines and the active regions 100a form the memory cells of the non-volatile memory.

In view of the above, the select gate lines 142a and 142b are respectively disposed on the both outermost sides of the word lines, for example. The intersections between the select gate lines 142a and 142b and the active regions 100a respectively form select units of the non-volatile memory. Herein, the portion of the active regions 100a crossed by the select gate lines 142a and 142b form, for example, select gates of the select units.

As shown in FIG. 8D, the charge trapping layer 160 in the present embodiment is used in place of the floating gate described in the above-mentioned embodiment (shown in FIG. 6D) for forming the non-volatile memory. In the present embodiment, the material used for fabricating the dielectric layer 130 over the charge trapping layer 160 is oxide. Further, the material used for fabricating the isolation structures 108 and the insulating layer 116 below the charge trapping layer 160 is also oxide. Hence, the dielectric layer 130 may be used as a top dielectric layer, and the isolation structures 108 and the insulating layer 116 may be used as a bottom dielectric layer to form a semiconductor-oxide-nitride-oxide-semiconductor (SONOS) non-volatile memory. It should be noted that, in another embodiment, a bottom dielectric layer and/or a top dielectric layer may not be disposed. Further, the materials used for fabricating the bottom dielectric layer and the top dielectric layer may be other suitable dielectric materials.

Certainly, the number of memory cells formed by the method for fabricating a non-volatile memory of the present invention is not limited by the drawings of the two aforementioned embodiments. In other embodiments, the number of memory cells may vary according to the actual requirements. Hence, the present invention is not limited thereto.

In view of the above, the method for fabricating a non-volatile memory of the present invention utilizes a patterned hard mask layer and a mask layer to define a gate structure and a doped region without performing a photolithography process and an etching process to complete the fabrication of the gate structure. In other words, the method for fabricating a non-volatile memory of the present invention utilizes a damascene process to construct a self-aligned structure when fabricating the gate structure. Hence, the present invention can greatly lower the difficulty and provide a better control to the fabrication process of the non-volatile memory in order to avoid the occurrence of misalignment.

Further, no photolithography process or etching process is directly performed to the conductor material, hence abnormal electrical punch-through in the memory cells caused by residues of the conductor material can be avoided.

In addition, the present invention utilizes simple procedure to fabricate a self-aligned gate structure. Moreover, according to the present invention, the number of photomasks used in a photolithography process is reduced. Hence, the manufacturing costs are greatly lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for fabricating a non-volatile memory, comprising:
providing a substrate;
forming a plurality of isolation structures in the substrate to define a plurality of active regions, wherein the isolation structures are arranged in parallel and protrude from the surface of the substrate;
forming a plurality of mask layers on the substrate, wherein the mask layers intersect the isolation structures, and a surface of each of the mask layers is higher than a surface of each of the isolation structures;
forming a plurality of doped regions in the substrate;
forming a plurality of insulating layers on the substrate between the mask layers, wherein the mask layers and the insulating layers are arranged alternately, and the material of the insulating layers and the material of the mask layers have different etch selectivities;
removing the mask layers to expose the substrate;
forming a tunneling dielectric layer on the substrate;
forming a plurality of floating gates on the substrate surrounded by the isolation structures and the insulating layers, wherein a surface of each of the floating gates is lower than a surface of each of the isolation structures;
forming an inter-gate dielectric layer on the substrate; and
forming a plurality of control gates between the insulating layers, wherein the control gates intersect the active regions.

2. The method of claim 1, further comprising forming a plurality of select gates and the control gates simultaneously after the inter-gate dielectric layer is formed on the substrate.

3. The method of claim 1, wherein a method for forming the floating gates comprises:
forming a first conductor layer on the substrate; and
removing a portion of the first conductor layer.

4. The method of claim 3, wherein a process for removing a portion of the first conductor layer comprises a dry etching process.

5. The method of claim 3, wherein a material used for fabricating the first conductor layer comprises doped polysilicon.

6. The method of claim 1, wherein the inter-gate dielectric layer comprises a silicon oxide/silicon nitride/silicon oxide layer.

7. The method of claim 1, wherein a method for forming the control gates between the insulating layers comprises:
forming a second conductor layer on the substrate; and
removing a portion of the second conductor layer to expose the surface of the insulating layers.

8. The method of claim 7, wherein a process for removing a portion of the second conductor layer comprises a chemical mechanical polishing process.

9. The method of claim 7, wherein a material used for forming the second conductor layer comprises doped polysilicon.

10. The method of claim 1, wherein a material used for forming the tunneling dielectric layer comprises silicon oxide.

11. A method for fabricating a non-volatile memory, comprising:
providing a substrate;
forming a plurality of isolation structures in the substrate to define a plurality of active regions, wherein the isolation structures are arranged in parallel and protrude from the surface of the substrate;
forming a plurality of mask layers on the substrate, wherein the mask layers intersect the isolation structures, and a surface of each of the mask layers is higher than a surface of each of the isolation structures;
forming a plurality of doped regions in the substrate;
forming a plurality of insulating layers on the substrate between the mask layers, wherein the mask layers and the insulating layers are arranged alternately, and the material of the insulating layers and the material of the mask layers have different etch selectivities;
removing the mask layers to expose the substrate;
forming a tunneling dielectric layer on the substrate;
forming a charge trapping layer conformally on the substrate; and
forming a plurality of control gates between the insulating layers, wherein the control gates intersect the active regions.

12. The method of claim 11, after the formation of the charge trapping layer on the substrate, further comprising:
removing a portion of the charge trapping layer for forming a plurality of select gates; and
forming the control gates and the select gates simultaneously.

13. The method of claim 11, further comprising forming a top dielectric layer between the charge trapping layer and the control gates.

14. The method of claim 13, wherein a material used for fabricating the top dielectric layer comprises silicon oxide or aluminum oxide.

15. The method of claim 11, wherein a material used for fabricating the charge trapping layer comprises silicon nitride.

16. The method of claim 11, wherein a method for forming the control gates between the insulating layers comprises:
forming a conductor layer on the substrate; and
removing a portion of the conductor layer to expose the surface of the insulating layers.

17. The method of claim 16, wherein a process for removing a portion of the conductor layer comprises a chemical mechanical polishing process.

18. The method of claim 16, wherein a material used for fabricating the conductor layer comprises doped polysilicon.

19. The method of claim 11, wherein a material used for forming the tunneling dielectric layer comprises silicon oxide.
